(19) United States
(12) Patent Application Publication
(10) Pub. No.: US 2013/0126833 A1
(43) Pub. Date: May 23, 2013

(54) METHOD OF MANUFACTURING ORGANIC EL APPARATUS

(71) Applicant: CANON KABUSHIKI KAISHA, Tokyo (JP)

(72) Inventors: Taro Endo, Kawasaki-shi (JP); Nobuhiko Sato, Mobara-shi (JP)

(73) Assignee: CANON KABUSHIKI KAISHA, Tokyo (JP)

(21) Appl. No.: 13/677,119

(22) Filed: Nov. 14, 2012

(30) Foreign Application Priority Data
Nov. 18, 2011 (JP) 2011-253068

(51) Int. Cl. G03F 7/00; H01L 51/50

(52) U.S. Cl. CPC G03F 7/0005; H01L 51/5012
USPC 257/40; 430/314

(57) ABSTRACT

In a method of manufacturing an organic EL apparatus, a mask layer is formed on an organic compound layer, and a region not covered with the mask layer is patterned by dry etching, in which a charge injection layer is formed using an inorganic compound that has a low etching rate with respect to an etching gas used for patterning of the organic compound layer and that is not decomposed even when exposed to the etching gas.

### BACKGROUND OF THE INVENTION

1. Field of the Invention

The present invention relates to a method of manufacturing an organic EL apparatus.

2. Description of the Related Art

A technique for patterning organic compound layers using photolithography in a method of manufacturing an organic EL apparatus has been known. Japanese Patent No. 4145571 discloses a method in which a light-emitting layer is formed on a charge injection layer, a photoresist layer is formed in a predetermined pattern on the light-emitting layer, and then the light-emitting layer in a region not covered with the photoresist layer is removed by dry etching without removing the charge injection layer, thus performing patterning. According to this method, it is not necessary to redeposit a charge injection layer each time a light-emitting layer is subjected to patterning, and only one step of depositing a charge injection layer is needed. Therefore, the manufacturing efficiency is high, and also wastage of materials can be reduced.

An organic EL apparatus includes a plurality of organic EL elements, each having a structure in which organic compound layers including a light-emitting layer are interposed between a pair of electrodes. In the organic EL element, holes and electrons are injected from one electrode and from another electrode, respectively, into the organic compound layers, and holes and electrons are recombined in the light-emitting layer to produce light. The organic compound layers may include, in addition to the light-emitting layer, known functional layers. In Japanese Patent No. 4145571, a charge injection layer is provided as a functional layer in order to inject charges into the light-emitting layer in a balanced manner and to improve the luminous efficiency.

Japanese Patent No. 4145571 discloses that an organic compound or an inorganic oxide is deposited, as the charge injection layer, by a coating method. Regarding a film formed by a coating method, organic substances, such as a solvent, a precursor for the film material, and the like, used in the coating process may remain in the film in some cases. It is believed that, when such a charge injection layer is exposed to an etching gas, the organic substances remaining on the surface react with the etching gas, resulting in roughening of the surface profile or alteration of film properties in the surface. Consequently, when a charge injection layer is formed by a coating method as in Japanese Patent No. 4145571, in the step of patterning an organic compound layer by dry etching, the surface of the electron injection layer may be roughened or film properties may be altered, resulting in a decrease in charge injection efficiency. Even when a light-emitting layer is stacked on such a charge injection layer, it is not possible to improve the light-emitting characteristics of the organic EL apparatus.

### SUMMARY OF THE INVENTION

The present invention provides a method of manufacturing an organic EL apparatus having excellent light-emitting characteristics in which it is not necessary to redeposit a charge injection layer for each patterning of an organic compound layer and charges can be efficiently injected from electrodes.

In an aspect of the present invention, there is provided a method of manufacturing an organic EL apparatus that includes a first electrode, a second electrode, and a charge injection layer and an organic compound layer interposed between the first electrode and the second electrode, the method including a step (i) of forming, by a vacuum film formation process, a charge injection layer composed of an inorganic compound on a first electrode, a step (ii) of forming an organic compound layer on the charge injection layer, a step (iii) of selectively forming a mask layer in a predetermined region on the organic compound layer, and a step (iv) of exposing the charge injection layer by removing, by dry etching, the organic compound layer in a region not provided with the mask layer, in which the steps (ii) to (iv) are repeated two or more times.

According to the present invention, a charge injection layer composed of an inorganic compound is formed by a vacuum film formation process. The charge injection layer composed of an inorganic compound formed by the vacuum film formation process is unlikely to be etched or altered even when exposed to an etching gas. Therefore, good charge injection performance can be maintained even after patterning of the organic compound layer by dry etching, and it is possible to manufacture an organic EL apparatus having excellent light-emitting characteristics.

Further features of the present invention will become apparent from the following description of exemplary embodiments with reference to the attached drawings.

### BRIEF DESCRIPTION OF THE DRAWINGS

FIGS. 1A to 1L are cross-sectional views showing steps in a method of manufacturing an organic EL apparatus according to a first embodiment of the present invention.

FIGS. 2A to 2K are cross-sectional views showing steps in a method of manufacturing an organic EL apparatus according to a second embodiment of the present invention.

FIGS. 3A to 3D are cross-sectional views showing some of the steps in a method of manufacturing an organic EL apparatus according to Example 2.

FIG. 4 is a perspective view schematically showing an organic EL apparatus according to the present invention.

### DESCRIPTION OF THE EMBODIMENTS

Embodiments of an organic EL apparatus according to the present invention will be described with reference to the drawings. Techniques well known in the art or publicly known can be applied to portions not particularly illustrated or described. It is to be noted that the embodiments described below are merely examples and the present invention is not limited thereto. The embodiments may be used in combination.

### First Embodiment

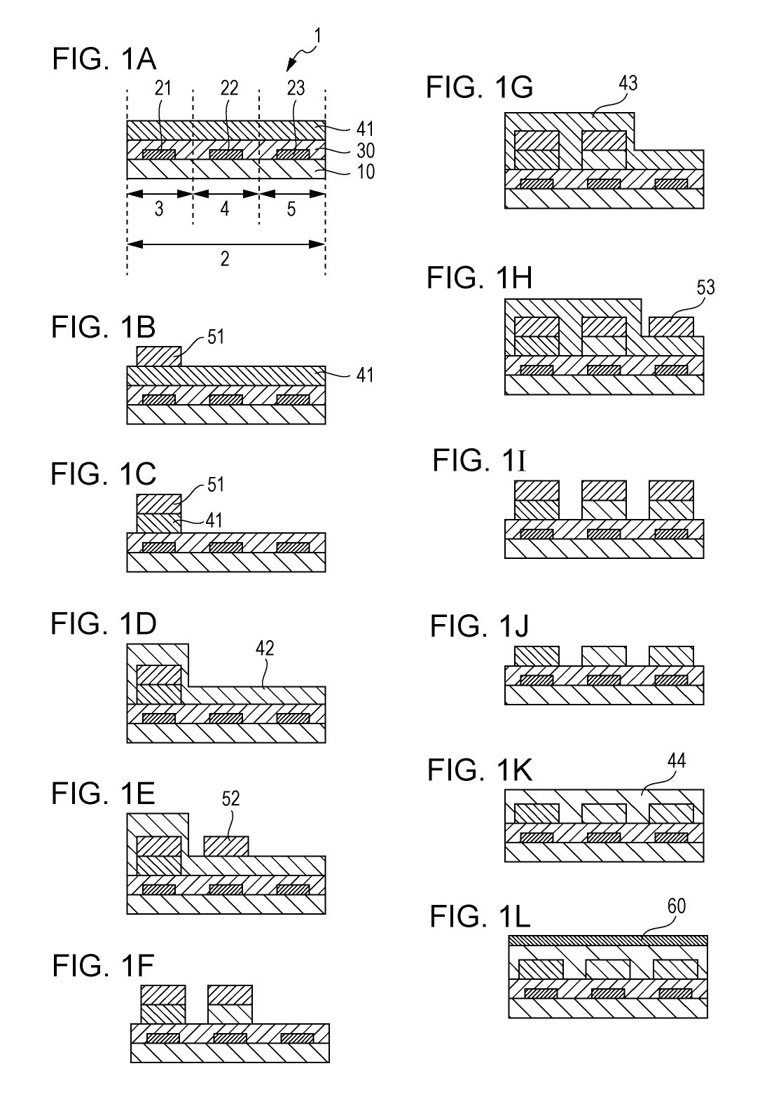

FIGS. 1A to 1L are cross-sectional views showing steps in a method of manufacturing an organic EL apparatus according to a first embodiment of the present invention.

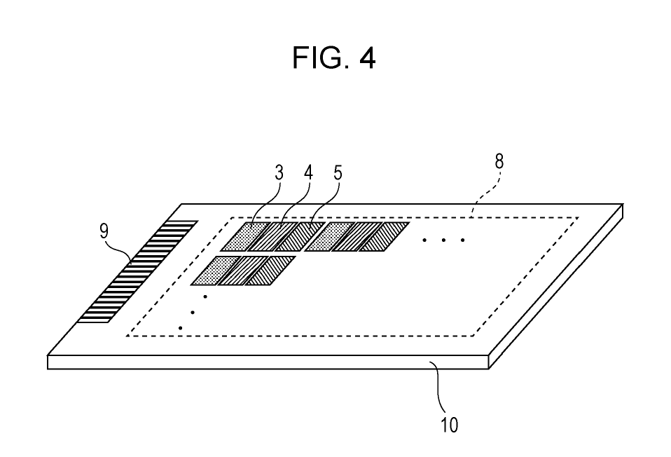

The organic EL apparatus has a first subpixel 3, a second subpixel 4, and a third subpixel 5 which display different colors on a substrate 10. FIG. 4 is a perspective view schematically showing the organic EL apparatus. The substrate 10 is provided with a display area 8 and external connection terminals 9. First subpixels 3, second subpixels 4, and third subpixels 5 are two-dimensionally arrayed in the display area 8. The external connection terminals 9 are electrically connected to circuits (not shown) by interconnect lines (not shown).

The first subpixel 3, the second subpixel 4, and the third subpixel 5 are each provided with an organic EL element having an organic compound layer interposed between a first electrode and a second electrode, and the first to third subpixels constitute a pixel 2. The pixel 2 is the minimum unit when the organic EL apparatus displays an image. Although FIGS. 1A to 1L show only one pixel 2, in the actual organic EL apparatus, a plurality of pixels 2 are arranged on the substrate 10. Furthermore, first electrodes 21, 22, and 23 are connected to circuits including transistors and the like (not shown) disposed on the substrate 10.

A method of manufacturing an organic EL apparatus according to the first embodiment will be described below with reference to FIGS. 1A to 1L.

### (Step of Forming First Electrode)

First, first electrodes 21, 22 and 23 are formed for corresponding subpixels on the substrate 10. Although the first electrode is described as an anode electrode in this embodiment, the first electrode may be a cathode electrode. The material for the first electrodes 21, 22 and 23 is selected depending on the light emission direction. In the case where light is emitted from the substrate 10 side (bottom emission type), a light-transmissive conductive material is used. In the case where light is emitted from the side opposite the substrate 10 (top emission type), a light-reflective metal material is used. In this example, since an organic EL apparatus of top emission type is fabricated, the first electrodes 21, 22 and 23 are composed of a light-reflective electrode material. As the light-reflective electrode material, a metal material, such as Cr, Al, Ag, Au, or Pt, may be suitably used. A material having a higher reflectance can more improve the light extraction efficiency.

In the case of an organic EL apparatus of top emission type, the second electrode 60, which will be described later, is composed of a light-transmissive electrode material. In the case of an organic EL apparatus of bottom emission type, the second electrode 60 may be composed of a light-reflective electrode material.

The first electrodes 21, 22 and 23 can be formed for corresponding subpixels by a vapor deposition method using a metal mask, a known photolithographic technique, or the like.

### (Step of Forming Charge Injection Layer)

A hole injection layer 30 composed of an inorganic compound, as a charge injection layer, is formed by a vacuum film formation process on the first electrodes 21, 22, and 23. The inorganic compound layer formed by the vacuum film formation process includes the inorganic compound material only. Unlike a coating method, there is no concern that impurities, such as a solvent and an organic precursor, will remain in the charge injection layer. Specific examples of the material for the hole injection layer 30 include molybdenum oxide, tungsten oxide, titanium oxide, titanium nitride, and vanadium pentoxide. As the vacuum film formation process, a known method, such as vacuum vapor deposition or sputtering, may be used. A method may be used in which a film of a metal material, such as molybdenum or tungsten, is formed, and then the film is subjected to oxidation treatment so as to be imparted with hole injection performance. In the case where the first electrode serves as a cathode, an electron injection layer composed of an inorganic compound may be formed as the charge injection layer. Specific examples of the material for the electron injection layer include LiF and Cs₂CO₃.

A thickness of the hole injection layer 30 exceeding about 100 nm results in resistance to flow of charges, and it becomes difficult to inject holes from the first electrodes 21, 22, and 23 serving as anode electrodes into the organic compound layer, which will be described later. Therefore, the thickness of the hole injection layer 30 can be less than 100 nm, such as about several nanometers to several tens of nanometers.

The hole injection layer 30 may be formed as a continuous film extending over the first electrodes 21, 22, and 23 as long as it covers the first electrodes, or may be formed separately in predetermined regions using a photolithographic technique or the like.

It is necessary to select the material for the hole injection layer 30 in consideration of an etching gas to be used in the step of removing the organic compound layer, which will be described later. Specifically, a material that is resistant to an etching gas to be used is selected. Being “resistant” is a property of the etching rate of the material for an etching gas being lower than that of the organic compound layer, and the material is not likely to be altered even when exposed to the etching gas. For example, in the case where the organic compound layer is subjected to dry etching using oxygen gas, the hole injection layer can be composed of an oxidized inorganic compound. Since the oxidized inorganic compound contains oxygen as a constituent, oxidation is not likely to occur, the etching rate with respect to oxygen gas, which is an etching gas, is low, and alteration does not substantially occur.

### (Step of Forming First Organic Compound Layer)

A first organic compound layer 41 is formed, using a known vapor deposition method or coating method, on the substrate 10 provided with the first electrodes 21, 22, and 23 (FIG. 1A). The first organic compound layer 41 is a single layer including at least a light-emitting layer, or a laminated body including, in addition to a light-emitting layer, functional layers, such as an electron transport layer, an electron injection layer, and a hole transport layer. In view of luminous efficiency, the first organic compound layer 41 can be an amorphous film. Furthermore, the thickness of the first organic compound layer 41 may be designed such that a film thickness interference effect can be obtained with respect to a specific emission wavelength.

### (Step of Forming Mask Layer in a Pattern)

A mask layer 51 is formed in a pattern on the first organic compound layer 41. Specifically, the mask layer 51 is formed in a region in which the first organic compound layer 41 is made to remain. In this embodiment, the mask layer 51 is selectively formed on the first organic compound layer 41 located in the region of the first subpixel 3 provided with the first electrode 21 (FIG. 1B).

For example, after a layer composed of a photosensitive resin is formed by a spin coating method, a dip coating method, or the like on the entire surface of the substrate provided with the first organic compound layer 41, patterning may be performed using photolithography to selectively form a mask layer 51 in a predetermined region. In the case where a method that can selectively form a material, such as an inkjet method or a printing method, is used, it is not necessary to perform patterning using photolithography.

In the step of forming the mask layer 51, there is a possibility that the first organic compound layer 41 may come into contact with a solvent contained in the photosensitive resin, a developer for the photosensitive resin layer, or the like. In the case where the first organic compound layer 41 is subjected to damage, such as dissolution or alteration, due to the solvent, the developer, or the like, a protective layer may be provided between the first organic compound layer 41 and the mask layer 51. As the protective layer, a film having high moisture resistance can be used. For example, silicon nitride, silicon oxide, silicon oxynitride, or the like may be used.

The mask layer 51 and the protective layer are removed from the surface of the first organic compound layer 41 in the end. Therefore, in the case where the mask layer 51 or the protective layer is composed of a material that is difficult to be removed from the surface of the first organic compound layer 41, an intermediate layer (not shown) can be provided between the organic compound layer and the mask layer 51 or the protective layer. The intermediate layer is provided in order to easily remove the mask layer 51 and the protective layer formed thereon from the surface of the organic compound layer without damaging the organic compound layer. Consequently, for the intermediate layer, a material that has a high solubility in a liquid in which the solubility of the first organic compound layer 41 is low and that does not damage the first organic compound layer 41 during formation is selected. In other words, for the intermediate layer, a material is selected such that the etching rate of the intermediate layer with respect to the solution is higher than that of the first organic compound layer. For example, in the case where the first organic compound layer 41 is composed of a material that hardly dissolves in water, water can be suitably used as a solution that dissolves the intermediate layer. In such a case, as the intermediate layer, a water-soluble inorganic material, such as LiF or NaCl, or a water-soluble polymer, such as polyvinyl alcohol (PVA) or polyvinylpyrrolidone (PVP), may be suitably used.

### (Step of Removing First Organic Compound Layer by Dry Etching)

By exposing the substrate 10 having the mask layer 51 formed in a pattern to an etching gas, the first organic compound layer 41 in a region not covered with the mask layer 51 is removed (FIG. 1C). Dry etching using oxygen gas may be suitably used to remove the first organic compound layer 41 and other layers composed of organic compound materials.

When the first organic compound layer 41 is removed in the last stage of this step, the hole injection layer 30 formed on the first electrodes 22 and 23 is exposed to the etching gas. However, the inorganic compound constituting the hole injection layer 30 is difficult to react with oxygen gas, which is an etching gas, and the hole injection layer 30 does not contain a solvent, organic substances, or the like. Therefore, the hole injection layer 30 is not substantially altered before and after the etching step, and the charge injection performance can be maintained. By this step, the first organic compound layer 41 can be selectively formed on the first electrode 21 according to the pattern of the mask layer 51.

### (Step of Forming Second Organic Compound Layer on First Electrode 22)

As in the first organic compound layer 41, a second organic compound layer 42 is formed on the substrate 10 provided with the first organic compound layer 41 (FIG. 1D). Then, as in the mask layer 51, a mask layer 52 is selectively formed on the second organic compound layer 42 formed in the region of the second subpixel 4 provided with the first electrode 22 (FIG. 1E). Subsequently, the second organic compound layer 42 in a region not covered with the mask layer 52 is removed by dry etching using oxygen gas (FIG. 1F). Since the first organic compound layer 41 is covered with the mask layer 51 formed previously, the first organic compound layer 41 is not damaged by dry etching while the second organic compound layer 42 is being subjected to dry etching. By this step, the second organic compound layer 42 can be selectively formed on the first electrode according to the pattern of the mask layer 52. Since the mask layer 52 is not formed in the region of the third subpixel 5 provided with the first electrode 23, the second organic compound layer 42 is removed and the surface of the hole injection layer 30 is exposed. In this case, since the hole injection layer 30 is not substantially altered before and after the etching step, it is also possible to selectively remove the second organic compound layer 42 while maintaining the charge injection performance.

### (Step of Forming Third Organic Compound Layer on First Electrode 23)

As in the first organic compound layer 41, a third organic compound layer 43 is formed on the substrate 10 on which layers up to the second organic compound layer 42 have been disposed (FIG. 1G). A mask layer 53 is selectively formed on the third organic compound layer 43 located in the region of the third subpixel 5 provided with the first electrode 23 (FIG. 1H). Then, the third organic compound layer 43 in a region not covered with the mask layer 53 is removed by dry etching using oxygen gas (FIG. 1I). Since the first organic compound layer 41 and the second organic compound layer 42 are covered with the mask layer 51 and the mask layer 52, respectively, while the third organic compound layer 43 is being subjected to dry etching, they are not damaged by dry etching. By this step, the third organic compound layer 43 can be selectively formed on the first electrode 23 according to the pattern of the mask layer 53.

### (Step of Removing Mask Layers)

The mask layers 51 to 53 remaining on the first to third organic compound layers are removed because they block the flow of charges in the organic EL elements (FIG. 1J). In order to remove the mask layers, an existing method, such as wet etching or dry etching, may be used. In the case where wet etching is used, a solvent that selectively dissolves the mask layers can be used.

### (Step of Forming Common Organic Compound Layer)

After the first, second, and third organic compound layers included in the first, second, and third subpixels, respectively, are patterned and the mask layers are removed as described above, a common organic compound layer 44, which is common to the first to third subpixels, is formed (FIG. 1K). The material for the common organic compound layer 44 is not particularly limited as long as it is formed after the light-emitting layers, which are required to be patterned for corresponding subpixels, have been formed. In the case of this example in which the first electrodes 21 to 23 are anode electrodes, examples of the common organic compound layer 44 include an electron injection layer and an electron transport layer. As the material for the electron injection layer, an electron-transporting material to which an alkali metal, such as cesium or lithium, is added can be used.

### (Step of Forming Second Electrode)

A second electrode 60 is formed on the common organic compound layer 44 (FIG. 1L). The second electrode 60 can be light-transmissive or semi-transmissive. In the case of a light-transmissive electrode, a transparent conductive material, such as indium tin oxide, indium zinc oxide, or zinc oxide, or an organic conductive material, such as polyacetylene, may be suitably used. In the case of a semi-transmissive electrode, a thin film composed of a metal material, such as Ag or Al, with a thickness of about 10 to 30 nm may be used, or a laminated body including a thin film composed of a metal material and a film composed of a transparent conductive material may be used. The term “light-transmissive” refers to a property in which the transmittance with respect to visible light is 80% or more, and the term “semi-transmissive” refers to a property in which the transmittance with respect to light with wavelengths in the visible light range is 20% or more and less than 80%. The second electrode may be formed by a known method, such as sputtering or vacuum vapor deposition.

Finally, in order to prevent degradation of pixels due to entry of moisture into the organic EL apparatus from the outside, a known sealing member (not shown) can be provided.

### Second Embodiment

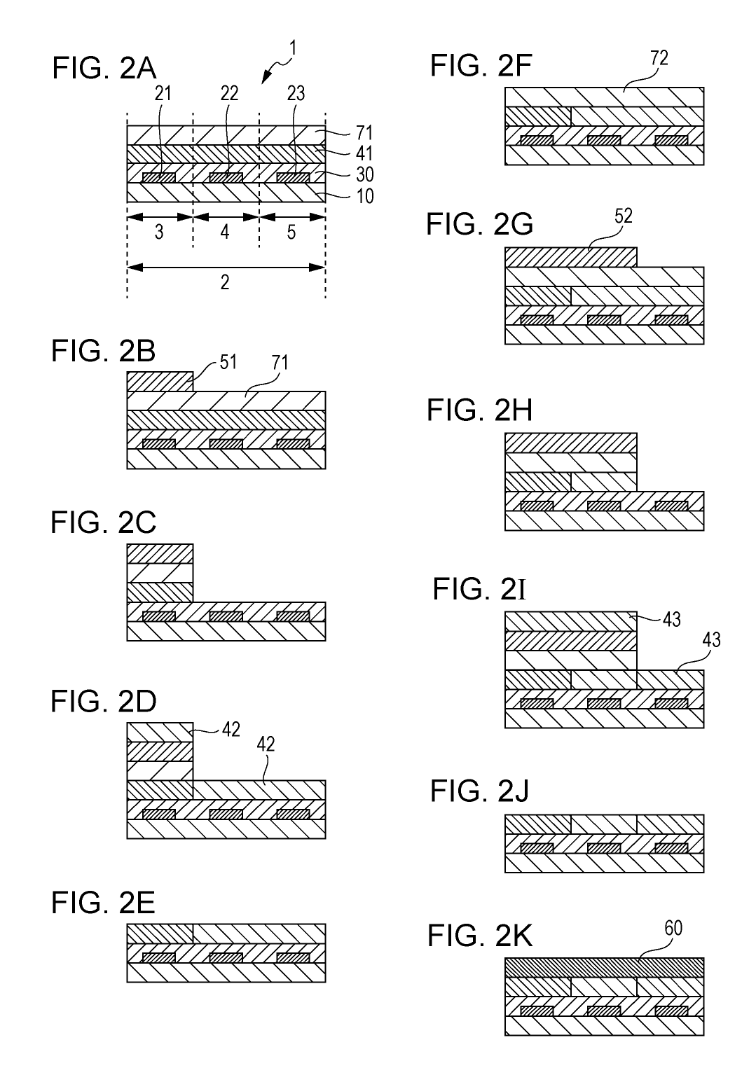

FIGS. 2A to 2K are cross-sectional views showing steps in a method of manufacturing an organic EL apparatus according to a second embodiment of the present invention. This embodiment differs from the first embodiment in that an intermediate layer is provided between an organic compound layer and a mask layer, and a lift-off process using the intermediate layer is included. Detailed description of features common to the first embodiment will be omitted.

First electrodes 21, 22, and 23 are formed as in the first embodiment, and a hole injection layer 30 composed of an inorganic compound, a first organic compound layer 41, and an intermediate layer 71 are formed thereon in that order (FIG. 2A).

The intermediate layer 71 is provided in order to remove films formed on and above the intermediate layer from the surface of the organic compound layer without damaging the organic compound layer. Consequently, for the intermediate layer 71, a material that has a high solubility in a liquid in which the solubility of the first organic compound layer 41 is low and that does not damage the first organic compound layer 41 during formation is selected. In other words, for the intermediate layer 71, a material is selected such that the etching rate of the intermediate layer 71 with respect to the solution is higher than that of the first organic compound layer 41. For example, in the case where the first organic compound layer 41 is composed of a material that hardly dissolves in water, water can be suitably used as a solution that dissolves the intermediate layer 71. In such a case, as the intermediate layer 71, a water-soluble inorganic material, such as LiF or NaCl, or a water-soluble polymer, such as polyvinyl alcohol (PVA) or polyvinylpyrrolidone (PVP), may be suitably used.

A mask layer 51 is selectively formed on the intermediate layer 71 provided on the first electrode 21 (FIG. 2B). The substrate 10 on which the mask layer 51 has been formed in a pattern is exposed to an etching gas, and thereby the intermediate layer 71 and the first organic compound layer 41 in a region not covered with the mask layer 51 are removed by dry etching (FIG. 2C). When the first organic compound layer 41 is removed in the last stage of this step, the hole injection layer 30 formed on the first electrodes 22 and 23 is exposed to the etching gas. However, the inorganic compound constituting the hole injection layer 30 is difficult to react with oxygen, which is an etching gas, and the injection performance of the hole injection layer 30 can be maintained before and after the etching step. By this step, the first organic compound layer 41 can be selectively formed on the first electrode according to the pattern of the mask layer 51.

A second organic compound layer 42 is formed on the substrate 10 on which the intermediate layer 71 remains in a pattern (FIG. 2D). Subsequently, the intermediate layer 71 is brought into contact with a solution so as to be selectively dissolved, and thereby the second organic compound 42 disposed on the intermediate layer 71 is lifted off (FIG. 2E). An intermediate layer 72 is newly formed on the substrate 10 on which the first organic compound layer 41 remains on the first electrode 21 and the second organic compound layer 42 remains on the first electrodes 22 and 23 (FIG. 2F). A mask layer 52 is selectively formed over the region of the first electrodes 21 and 22 (FIG. 2G). The second organic compound layer 42 in a region not covered with the mask layer 52 is removed by dry etching (FIG. 2H). As in the dry etching step for the first organic compound layer 41, in the last stage of this step, the hole injection layer 30 formed on the first electrode 23 is exposed to the etching gas. However, the inorganic compound constituting the hole injection layer 30 is difficult to react with oxygen, which is an etching gas, and it is possible to selectively remove the second organic compound layer 42 while maintaining the injection performance of the hole injection layer 30.

After the second organic compound layer 42 formed on the first electrode 23 is removed, a third organic compound layer 43 is formed (FIG. 2I). Subsequently, the intermediate layer 72 is brought into contact with a solution so as to be selectively dissolved, and thereby the third organic compound 43 disposed on the intermediate layer 72 is lifted off. Thus, patterning of the first, second, and third organic compound layers included in the first, second, and third subpixels, respectively, is completed (FIG. 2J).

A common second electrode 60 is formed on the first organic compound layer 41, the second organic compound layer 42, and the third organic compound layer 43. Thereby, a basic structure of the organic EL apparatus is completed (FIG. 2K). As in the first embodiment, prior to the formation of the second electrode, a common organic compound layer 44 common to the first to third subpixels may be formed. Furthermore, in order to prevent degradation of pixels due to entry of moisture into the organic EL apparatus from the outside, a known sealing member (not shown) can be provided.

When a lift-off process using an intermediate layer is used as in this embodiment, the number of steps of selectively forming a mask layer can be reduced and the manufacturing process can be simplified.

### Example 1

In this example, a full-color organic EL apparatus was fabricated, in which emission colors of light-emitting layers (first light-emitting layer, second light-emitting layer, and third light-emitting layer) contained in organic compound layers 41, 42, and 43 were green, blue, and red, respectively. It is to be noted that the combination of emission colors is not particularly limited. Furthermore, in this example, each of the organic compound layers was configured to have three layers: a hole transport layer, a light-emitting layer, and an electron transport layer.

The organic EL apparatus was fabricated according to the steps shown in FIGS. 1A to 1L.

First, a substrate 10 provided with circuits (not shown) was prepared, and an aluminum layer was formed by sputtering over the entire substrate surface provided with the circuits. The aluminum layer was patterned for each subpixel using a known photolithographic technique to form first electrodes 21, 22, and 23. An insulating layer was provided between the circuits and the first electrodes, and the circuits were connected to predetermined first electrodes through contact holes provided in the insulating layer.

Molybdenum oxide was deposited by vacuum vapor deposition with a thickness of 2 nm over the entire substrate surface provided with the first electrodes to form a hole injection layer 30. Using known organic compound materials, a hole transport layer, a first light-emitting layer emitting green light, and an electron transport layer were deposited in that order by vapor deposition over the entire substrate surface provided with the hole injection layer 30. Thereby, a first organic compound layer 41 was formed. The total thickness of the first organic compound layer 41 was 160 nm.

A positive-type photoresist (manufactured by AZ Electronic Materials; trade name: “AZ1500”) was applied by spin coating onto the entire surface of the first organic compound layer. Then, pre-baking was performed to form a photoresist layer with a thickness of 1,000 nm.

The photoresist layer was exposed to ultraviolet light through a photomask such that the photoresist layer remained in the region of the first subpixel 3. In the exposure process, an aligner “MPA600” manufactured by Canon was used. In this example, since a positive-type photosensitive resin was used, a photomask configured to block ultraviolet light such that a region in which the photosensitive material was made to remain was not exposed to light was used. In the case where a negative-type photosensitive resin is used, a photomask configured to block ultraviolet light such that a region in which the photosensitive layer is made to remain is exposed to light may be used.

After exposure was performed, using a 50% aqueous solution of an alkali developer (trade name: “312MIF”, manufactured by AZ Electronic Materials) as a developer, the exposed substrate was immersed in the developer for one minute to perform development. In this way, by performing patterning such that the photoresist layer remained in the region of the first subpixel 3 provided with the first electrode 21, a mask layer 51 was formed (FIG. 1B).

The first organic compound layer 41 in a region not covered with the mask layer (photoresist layer) 51 remaining on the substrate 10 was removed by dry etching using oxygen gas (FIG. 1C). Etching was performed for two minutes, using oxygen as a reaction gas, under the conditions of a flow rate of 30 sccm, a pressure of 10 Pa, and an output of 150 W. In this step, after the organic compound layer 41 was removed, the surface of the hole injection layer 30 was subjected to dry etching. In this example, molybdenum oxide constituting the hole injection layer 30 is not likely to be etched because oxygen serving as the reaction gas in dry etching is difficult to react with the inorganic compound. Therefore, the hole injection layer 30 was not removed or altered.

The first organic compound layer 41 in a region not covered with the photoresist layer 51 was subjected to dry etching, and then, as in the first organic compound layer 41, a second organic compound layer 42 including a second light-emitting layer emitting blue light was deposited by vapor deposition (FIG. 1D). A photoresist layer was formed on the second organic compound layer 42 formed in the region of the second subpixel 4 provided with the first electrode 22, and patterning was performed to form a mask layer 52 (FIG. 1E). The mask layer (photoresist layer) 52 was formed in the same manner as that in the mask layer 51 in the region of the first subpixel 3. The second organic compound layer 42 in a region not covered with the mask layer 52 was removed by dry etching under the same conditions as those for the dry etching of the first organic compound layer 41 (FIG. 1F).

As in the second organic compound layer 42, a third organic compound layer 43 including a third light-emitting layer emitting red light was formed. Then, a photoresist layer was formed, and patterning was performed to form a mask layer 53. The third organic compound layer in a region not covered with the mask layer (photoresist layer) 53 was removed. Thereby, the third organic compound layer was selectively formed in the region of the third subpixel 5 provided with the first electrode 23 (FIGS. 1G to 11).

The mask layers were disposed on the first to third subpixels. Accordingly, the photoresist layers 51 to 53 were removed by dry etching, using oxygen as a reaction gas, under the conditions of a flow rate of 20 sccm, a pressure of 8 Pa, an output of 150 W, and a process time of 3 minutes (FIG. 1J). Thus, patterning of the organic compound layers in the first to third subpixels was completed.

After the patterning of the organic compound layers in the first to third subpixels was performed, an electron injection layer was formed, using a known material, as a common organic compound layer 44 continuously extending over the first to third subpixels (FIG. 1K). A second electrode 60 was formed so as to extend over the first to third subpixels by depositing by sputtering indium zinc oxide with a thickness of 30 nm on the common organic compound layer 44. Thereby, an organic EL apparatus was completed (FIG. 1L). The second electrode 60 was connected to a circuit (not shown) provided on the substrate 10. Finally, as a sealing member, a glass cap was bonded to the substrate 10 using an ultraviolet-curable resin.

As a comparative example, an organic EL apparatus was fabricated as in Example 1 except that a hole injection layer 30 was formed by a coating method using polyethylene dioxythiophene/polystyrene sulfonate.

Electric power was supplied to each of the resulting organic EL apparatuses through a circuit, and a comparison was made regarding the driving voltage at the time of white display. As a result, the driving voltage was about 10 V in the organic EL apparatus of the comparative example, while the driving voltage was about 4 V in the organic EL apparatus of this example. This shows that, by the manufacturing method according to this example, it is possible to provide an organic EL apparatus in which the manufacturing efficiency is high because it is not necessary to redeposit a charge injection layer for each patterning of a light-emitting layer and in which good light-emitting characteristics are exhibited by a low driving voltage.

### Example 2

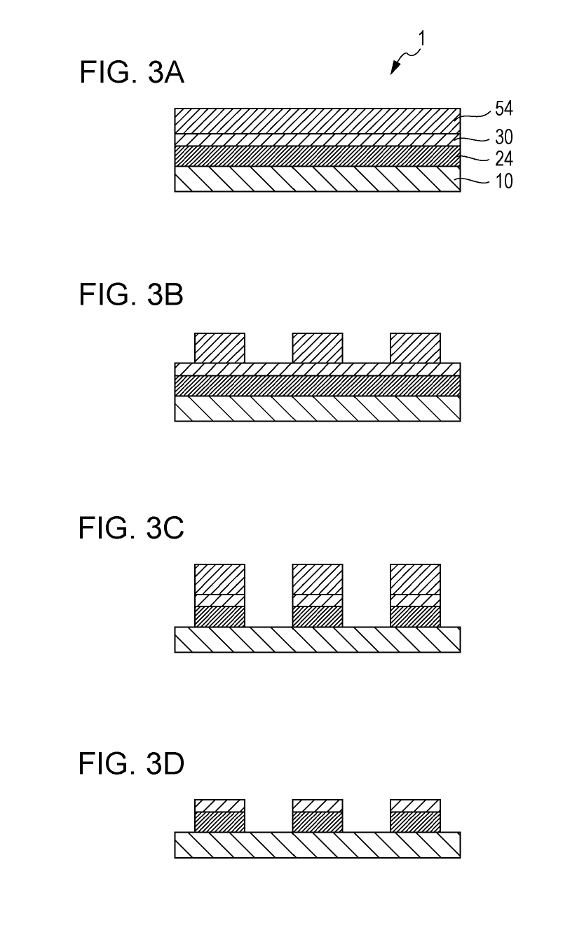

FIGS. 3A to 3D are schematic cross-sectional views showing an organic EL apparatus according to Example 2. This example differs from Example 1 in that a first electrode and a hole injection layer are patterned for each subpixel. Patterning of the first electrode and the hole injection layer will be described in detail below.

A first electrode layer 24 composed of aluminum and a hole injection layer 30 composed of molybdenum oxide were continuously formed by sputtering on a substrate 10 provided with circuits (not shown) (FIG. 3A).

A photoresist layer was formed on the hole injection layer, using the same photoresist as that in Example 1, by the same method as that in Example 1, and patterning was performed such that a mask layer 54 composed of the photoresist layer remained in the light-emitting region for each subpixel (FIG. 3B).

The hole injection layer 30 and the first electrode layer 24 in a region not covered with the mask layer (photoresist layer) 54 were removed by dry etching (FIG. 3C). The dry etching was performed, using carbon tetrafluoride as a reaction gas, under the conditions of a flow rate of 30 sccm, a pressure of 10 Pa, and an output of 150 W. Existing dry etching or wet etching may be appropriately selected and used depending on the material used for each layer.

After the patterning of the hole injection layer 30 and the first electrode 24 were completed, the mask layer 54 was removed by dissolving it in an organic solvent, acetone (FIG. 3D). The mask layer 54 may be removed by an existing method, such as wet etching using another solvent, or dry etching.

After the mask layer 54 was removed, first to third organic compound layers, a common organic compound layer, and a second electrode were formed as in Example 1. Thereby, a full-color organic EL apparatus 1 was fabricated. The resulting organic EL apparatus was compared to the organic EL apparatus fabricated in Example 1 regarding image quality by sequentially displaying the colors of red, blue, and green under the same conditions.

In the organic EL apparatus fabricated in Example 1, when red was displayed, weak emission also occurred in the adjacent blue and green subpixels, and color mixture was observed. The same applied when another color was displayed. However, in the organic EL apparatus according to this example, weak emission did not occur owing to a leakage current when a current was applied to the adjacent subpixel, and good image quality free from color mixture was obtained compared with the organic EL apparatus in Example 1. The reason for this is that since the hole injection layer 30 is patterned for each subpixel, movement of holes between subpixels was suppressed.

Furthermore, the driving voltage at the time of white display was measured as in Example 1. As a result, the driving voltage was low, comparable to that in Example 1.

In this example, in order to pattern the first electrode and the hole injection layer for each subpixel, after the first electrode 24 and the hole injection layer 30 are formed, the mask layer 54 is selectively formed, and using the mask layer 54, the first electrode 24 and the hole injection layer 30 are patterned. However, the manufacturing method is not limited thereto. The first electrode 24 and the hole injection layer 30 may be separately patterned. Specifically, a method may be used in which, after a first electrode is patterned for each subpixel as in Example 1, a hole injection layer 30 is formed, and by forming a mask layer anew in the light-emitting region for each subpixel, the hole injection layer 30 is patterned.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-253068 filed Nov. 18, 2011, which is hereby incorporated by reference herein in its entirety.

What is claimed is:

1. A method of manufacturing an organic EL apparatus that includes a first electrode, a second electrode, and a charge injection layer and an organic compound layer interposed between the first electrode and the second electrode, the method comprising:
a step (i) of forming, by a vacuum film formation process, a charge injection layer composed of an inorganic compound on a first electrode;
a step (ii) of forming a first organic compound layer on the charge injection layer;
a step (iii) of selectively forming a mask layer in a predetermined region on the first organic compound layer;
a step (iv) of exposing the charge injection layer by removing, by dry etching, the first organic compound layer in a region not provided with the mask layer,
a step (v) of forming a second organic compound layer on the exposed charge injection layer; and
a step (vi) of forming a second electrode on the first organic compound layer and the second organic compound layer.

2. The method of manufacturing an organic EL apparatus according to claim 1, wherein the step (iii) is performed using photolithography.

3. The method of manufacturing an organic EL apparatus according to claim 1, further comprising, between the step (ii) and the step (iii), a step of forming a protective layer composed of any one of silicon nitride, silicon oxide, and silicon oxynitride,
wherein, in the step (iv), the protective layer in the region not covered with the mask layer is removed.

4. The method of manufacturing an organic EL apparatus according to claim 3, further comprising, between the step (ii) and the step of forming the protective layer, a step of forming an intermediate layer composed of a water-soluble inorganic material or a water-soluble polymer,
wherein, in the step (iv), the intermediate layer in the region not covered with the mask layer is removed.

5. The method of manufacturing an organic EL apparatus according to claim 1, further comprising, between the step (ii) and the step (iii), a step of forming an intermediate layer composed of a water-soluble inorganic material or a water-soluble polymer,
wherein, in the step (iv), the intermediate layer in the region not covered with the mask layer is removed.

6. The method of manufacturing an organic EL apparatus according to claim 1, wherein an etching gas used in the step of exposing the charge injection layer contains oxygen, and the charge injection layer is composed of an oxidized inorganic compound.

7. The method of manufacturing an organic EL apparatus according to claim 6, wherein the inorganic compound is any one of molybdenum oxide, tungsten oxide, titanium oxide, and vanadium pentoxide.

8. The method of manufacturing an organic EL apparatus according to claim 6, wherein the charge injection layer has a thickness of less than 100 nm.

9. A method of manufacturing an organic EL apparatus that includes a first electrode, a second electrode, and a charge injection layer and an organic compound layer interposed between the first electrode and the second electrode, the organic compound layer being formed in a pattern, the method comprising:
a step (i) of forming, by a vacuum film formation process, a first electrode and a charge injection layer in that order;
a step (ii) of patterning the first electrode and the charge injection layer;
a step (iii) of forming a first organic compound layer on the charge injection layer;
a step (iv) of selectively forming a mask layer in a predetermined region on the first organic compound layer;
a step (v) of exposing the charge injection layer by removing, by dry etching, the first organic compound layer in a region not provided with the mask layer;
a step (vi) of forming a second organic compound layer on the exposed charge injection layer; and
a step (vii) of forming a second electrode on the first organic compound layer and the second organic compound layer;
wherein the step (ii) includes:
a step (ii-a) of forming a mask layer in a pattern on the charge injection layer;
a step (ii-b) of removing the first electrode and the charge injection layer in a region not provided with the mask layer; and
a step (ii-c) of removing the mask layer.

10. The method of manufacturing an organic EL apparatus according to claim 9, wherein the step (iv) is performed using photolithography.

11. The method of manufacturing an organic EL apparatus according to claim 9, further comprising, between the step (iii) and the step (iv), a step of forming a protective layer composed of any one of silicon nitride, silicon oxide, and silicon oxynitride,
wherein, in the step (v), the protective layer in the region not covered with the mask layer is removed.

12. The method of manufacturing an organic EL apparatus according to claim 11, further comprising, between the step (iii) and the step of forming the protective layer, a step of forming an intermediate layer composed of a water-soluble inorganic material or a water-soluble polymer,
wherein, in the step (v), the intermediate layer in the region not covered with the mask layer is removed.

13. The method of manufacturing an organic EL apparatus according to claim 9, further comprising, between the step (iii) and the step (iv), a step of forming an intermediate layer composed of a water-soluble inorganic material or a water-soluble polymer,
wherein, in the step (v), the intermediate layer in the region not covered with the mask layer is removed.

14. The method of manufacturing an organic EL apparatus according to claim 9, wherein an etching gas used in the step of exposing the charge injection layer contains oxygen, and the charge injection layer is composed of an oxidized inorganic compound.

15. The method of manufacturing an organic EL apparatus according to claim 14, wherein the inorganic compound is any one of molybdenum oxide, tungsten oxide, titanium oxide, and vanadium pentoxide.

16. The method of manufacturing an organic EL apparatus according to claim 14, wherein the charge injection layer has a thickness of less than 100 nm.

17. An organic EL apparatus manufactured by the method of manufacturing an organic EL apparatus according to claim 1.
